(19) United States
(12) Patent Application Publication
(10) Pub. No.: US 2024/0414902 A1
(43) Pub. Date: Dec. 12, 2024

(54) DISPLAY DEVICE

(71) Applicant: LG ELECTRONICS INC., Seoul (KR)

(72) Inventor: Kidoo HAN, Seoul (KR)

(73) Assignee: LG ELECTRONICS INC., Seoul (KR)

(21) Appl. No.: 18/660,710

(22) Filed: May 10, 2024

(30) Foreign Application Priority Data
Jun. 9, 2023 (KR) 10-2023-0073977

(51) Int. Cl. H05K 9/00

(52) U.S. Cl. CPC H05K 9/0081; H05K 9/0054

(57) ABSTRACT

A display device is provided. The display device of the present disclosure may include: a display panel; a frame which is disposed at a rear of the display panel, and to which the display panel is coupled; a substrate coupled to the frame at a rear of the frame; and a holder disposed between the frame and the substrate and coupled to the substrate, wherein: the frame and the holder may be electrically conductive; and the holder may include a body contacting the substrate, and a leg protruding from the body toward the frame and elastically deformed while being in contact with the frame.

### CROSS-REFERENCE TO RELATED APPLICATION

Pursuant to 35 U.S.C. § 119 (a), this application claims the benefit of earlier filing date and right of priority to Korean Patent Application No. 10-2023-0073977, filed on Jun. 9, 2023, the contents of which are hereby incorporated by reference herein in its entirety.

### BACKGROUND OF THE INVENTION

### Field of the Invention

The present disclosure relates to a display device.

### Description of the Related Art

With the development of the information society, there have been growing demands for various types of display devices, and in order to meet these demands, various display devices, such as a liquid crystal display (LCD) device, a plasma display panel (PDP), an electroluminescent display (ELD), a vacuum fluorescent display (VFD), etc., have been studied and used recently.

Among these devices, the LCD panel includes a TFT substrate and a color substrate which are positioned opposite each other with a liquid crystal layer interposed therebetween, and displays an image by using light provided by a backlight unit. Further, an organic light emitting diode (OLED) panel displays an image by using a self-emitting organic layer deposited on a substrate on which transparent electrodes are formed.

A source PCB provides digital video data and timing control signals, which are transmitted from a timing controller board, to a display panel. A structure for reducing Electromagnetic Interference (EMI) noise in a substrate, such as the source PCB, is being actively researched.

### SUMMARY OF THE INVENTION

It is an objective of the present disclosure to solve the above and other problems.

Another objective of the present disclosure may be to provide a structure for allowing a substrate to make ground contact with a frame.

Another objective of the present disclosure may be to provide a structure for reducing Electromagnetic Interference (EMI) noise in a substrate.

Another objective of the present disclosure may be to provide a structure for minimizing sagging of a substrate toward a frame.

Another objective of the present disclosure may be to provide various examples of a holder that supports a substrate on a frame.

In accordance with an aspect of the present disclosure, the above and other objectives can be accomplished by providing a display device including: a display panel; a frame which is disposed at a rear of the display panel, and to which the display panel is coupled; a substrate coupled to the frame at a rear of the frame; and a holder disposed between the frame and the substrate and coupled to the substrate, wherein: the frame and the holder are electrically conductive; and the holder includes a body contacting the substrate, and a leg protruding from the body toward the frame and elastically deformed while being in contact with the frame.

### BRIEF DESCRIPTION OF THE DRAWINGS

The above and other objects, features and advantages of the present disclosure will be more apparent from the following detailed description in conjunction with the accompanying drawings, in which:

FIGS. 1 to 25 are diagrams illustrating examples of a display device according to embodiments of the present disclosure.

### DETAILED DESCRIPTION

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the case of the description, and do not have a distinguishing meaning or role.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

It should be understood that the terms, “comprise,” “include,” “have,” etc. when used in this specification, specify the presence of stated features, integers, steps, operations, elements, components, or combinations thereof but do not preclude the presence or addition of one or more other features, integers, steps, operations, elements, components, or combinations thereof.

References to directions, such as up (U), down (D), left (Le), right (Ri), front (F), and rear (R), shown in the drawings are provided merely for convenience of explanation and are not intended for limiting the scope of the present disclosure.

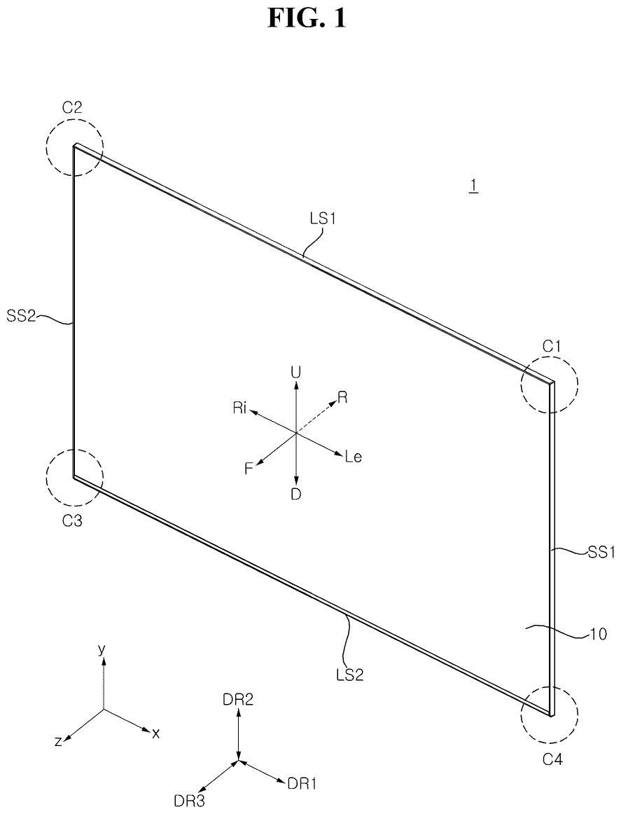

Referring to FIG. 1, a display device 1 may include a display panel 10. The display panel 10 may display an image.

The display device 1 may include a first long side LS1, a second long side LS2 opposite to the first long side LS1, a first short side SS1 adjacent to the first long side LS1 and the second long side LS2, and a second short side SS2 opposite to the first short side SS1. For convenience of explanation, it is illustrated and described that the first and second long sides LS1 and LS2 are longer than the first and second short sides SS1 and SS2, but it is also possible that lengths of the first and second long sides LS1 and LS2 may be approximately equal to lengths of the first and second short sides SS1 and SS2.

A direction parallel to the long sides LS1 and LS2 of the display device 1 may be referred to as a left-right direction or a first direction DR1. A direction parallel to the short sides SS1 and SS2 of the display device 1 may be referred to as an up-down direction or a second direction DR2. A direction perpendicular to the long sides LS1 and LS2 and the short sides SS1 and SS2 of the display device 1 may be referred to as a front-rear direction or a third direction DR3.

A side on which the display panel 10 displays an image may be referred to as a front side F, z, and a side opposite thereto may be referred to as a rear side R. The first long side LS1 may be referred to as an upper side U, y, and the second long side LS2 may be referred to as a lower side D. The first short side SS1 may be referred to as a left side Le, x, and the second short side SS2 may be referred to as a right side Ri.

The first long side LS1, the second long side LS2, the first short side SS1, and the second short side SS2 may be referred to as edges of the display device 1. Further, positions where the first long side LS1, the second long side LS2, the first short side SS1, and the second short side SS2 meet each other may be referred to as corners.

For example, a position where the first short side SS1 and the first long side LS1 meet each other may be referred to as a first corner C1. A position where the first long side LS1 and the second short side SS2 meet each other may be referred to as a second corner C2. A position where the second short side SS2 and the second long side LS2 meet each other may be referred to as a third corner C3. A position where the second long side LS2 and the first short side SS1 meet each other may be referred to as a fourth corner C4.

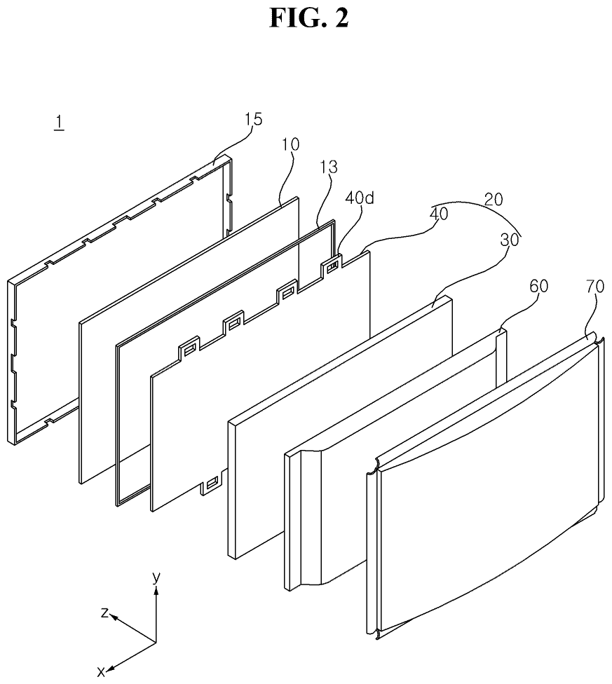

Referring to FIG. 2, the display device 1 may include the display panel 10, a front cover 15, a guide panel 13, a backlight unit 20, a frame 60, and a back cover 70.

The display panel 10 may form a front surface of the display device 1 and may display an image. The display panel 10 may display an image by outputting red, green or blue (RGB) for each pixel by a plurality of pixels on timing. The display panel 10 may be divided into an active area, in which the image is displayed, and a de-active area in which the image is not displayed. The display panel 10 may include a front substrate and a rear substrate which are opposite each other with a liquid crystal layer sandwiched therebetween. The display panel 10 may be referred to as an LCD panel 10.

The front substrate may include a plurality of pixels made up of red (R), green (G), and blue (B) subpixels. The front substrate may emit light corresponding to red, green, or blue color in response to a control signal.

The rear substrate may include switching elements. The rear substrate may switch on or off pixel electrodes. For example, the pixel electrode may change a molecular arrangement of a liquid crystal layer in response to a control signal received from the outside. The liquid crystal layer may include liquid crystal molecules. The arrangement of the liquid crystal molecules may be changed depending on a voltage difference between the pixel electrode and a common electrode. The liquid crystal layer may transmit light, provided from the backlight unit 20, to the front substrate or may block the light.

A front cover 15 may cover at least a partial area of the front surface and side surface of the display panel 10. The front cover 15 may be divided into a front surface cover disposed on the front surface of the display panel 10, and a side surface cover disposed on the side surface of the display panel 10. The front surface cover and the side surface cover may be provided separately or may be formed as one body. At least one of the front surface cover and the side surface cover may be omitted. The front cover 15 may be referred to as a case top 15 or an outer frame 15.

The guide panel 13 may surround a periphery of the display panel 10 and may cover the side surface of the display panel 10. The guide panel 13 may be coupled to the display panel 10 or may support the display panel 10. The guide panel 13 may be referred to as a middle cabinet 13, a panel guide 13, an inner guide 13, or an inner frame 13.

The backlight unit 20 may be disposed at the rear of the display panel 10. The backlight unit 20 may include a plurality of light sources. The backlight unit 20 may be coupled to the frame 60 at the front of the frame 60. The backlight unit 20 may be driven by a full driving scheme or a partial driving scheme such as local dimming, impulsive driving, or the like. The backlight unit 20 may include an optical sheet 40 and an optical layer 30.

The optical sheet 40 may evenly transmit light from the light source to the display panel 10. The optical sheet 40 may be composed of a plurality of layers. For example, the optical sheet 40 may include a prism sheet, a diffusion sheet, and the like. For example, the optical sheet 40 may be a Double Brightness Enhance Film (DBEF). Meanwhile, a coupling part 40d of the optical sheet 40 may be coupled to the front cover 15, the frame 60, or the back cover 70.

The frame 60 may be disposed at the rear of the backlight unit 20 and may support components of the display device 1. For example, components, such as the backlight unit 20, a printed circuit board (PCB) on which a plurality of electronic elements are disposed, etc., may be coupled to the frame 60. For example, the frame 60 may be made of a metal material such as an aluminum alloy and the like. The frame 60 may be referred to as a main frame 60, a module cover 60, or a bottom cover 60.

The back cover 70 may cover the rear of the frame 60. The back cover 70 may be coupled to the frame 60 and/or the front cover 15. For example, the back cover 70 may be an injection-molded product of a resin material. In another example, the back cover 70 may be made of a metal material.

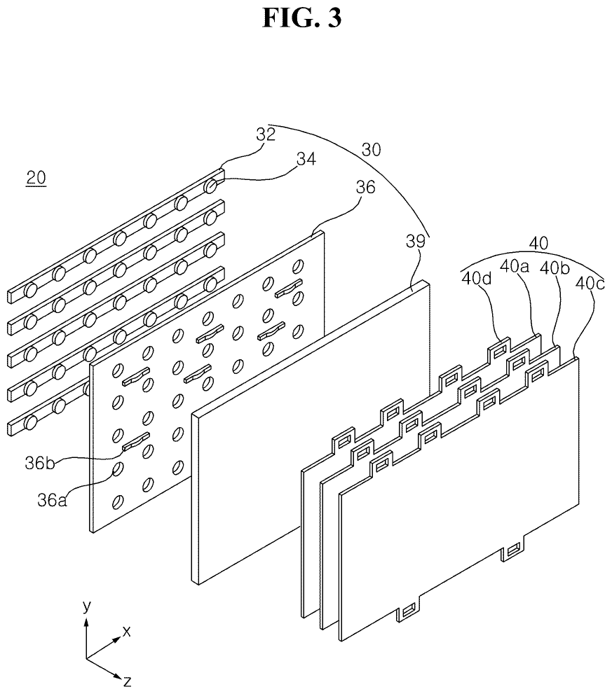

Referring to FIG. 3, the backlight unit 20 may include the optical layer 30 and the optical sheet 40. The optical layer 30 may include a substrate 32, at least one light source 34, a reflective sheet 36, and a diffusion plate 39.

The substrate 32 may be coupled to a front surface of the frame 60. The substrate 32 may have a plate shape or may have a plurality of straps that are vertically spaced apart from each other. The substrate 32 may be made of at least one of polyethylene terephthalate (PET), glass, polycarbonate (PC), and silicon. The substrate 32 may be a printed circuit board (PCB).

At least one light source 34 may be mounted on the substrate 32. A plurality of light sources 34 may be spaced apart from each other on the substrate 32. An electrode pattern for connecting an adapter and the light source 34 may be formed on the substrate 32. For example, a carbon nano tube (CNT) electrode pattern for connecting an adapter and the light source 34 may be formed on the substrate 32.

For example, the light source 34 may be a light emitting diode (LED) chip or an LED package including at least one LED chip. The light source 34 may be configured as a white LED or a colored LED emitting light of at least one of red, green, and blue colors, and the like. The colored LED may include at least one of a red LED, a green LED, and a blue LED. The light source 34 may be referred to as an optical assembly 34.

The reflective sheet 36 may be disposed at the front of the substrate 32. The reflective sheet 36 may be disposed on substrate 32, except a region where the light source 34 is formed. The reflective sheet 36 may have hole 36a in which the light sources 34 are disposed.

Further, the reflective sheet 36 may include at least one of a metal and metal oxide which are reflective materials. For example, the reflective sheet 36 may include a metal and/or metal oxide having high reflectance, such as at least one of aluminum (Al), silver (Ag), gold (Au), and titanium dioxide (TiO2). For example, a resin may be deposited or applied on the light source 34 and/or the reflective sheet 36. The resin may serve to diffuse light from the light source 34. Accordingly, the reflective sheet 36 may reflect light forward, which is provided from the light source 34 or reflected from the diffusion plate 39.

The diffusion plate 39 may be disposed at the front of the reflective sheet 36. The diffusion plate 39 may diffuse light from the light source 34. A spacer 36b may be disposed between the reflective sheet 36 and the diffusion plate 39 and may support a rear surface of the diffusion plate 39. Accordingly, an air gap may be formed between the reflective sheet 36 and the diffusion plate 39 and the light of the light source 34 may be spread widely by the air gap.

The optical sheet 40 may be disposed at the front of the diffusion plate 39. A rear surface of the optical sheet 40 may be in close contact with the diffusion plate 39, and a front surface of the optical sheet 40 may be in close contact with or adjacent to a rear surface of the display panel 10. The optical sheet 40 may include at least one sheet.

For example, the optical sheet 40 may include a plurality of sheets having different functions. A first optical sheet 40a may be a diffusion sheet, a second optical sheet 40b and a third optical sheet 40c may be prism sheets. The diffusion sheet may prevent light, emitted from the diffusion plate 39, from being partially concentrated, thereby providing uniform distribution of light. The prism sheet may collect light from the diffusion sheet 39 and may provide the light to the display panel 10. Meanwhile, the number and/or position of the diffusion sheet and the prism sheet may vary.

The coupling part 40d may be formed on at least one edge of the optical sheet 40. The coupling part 40d may be formed on at least one of the first optical sheet 40a, the second optical sheet 40b, and the third optical sheet 40c.

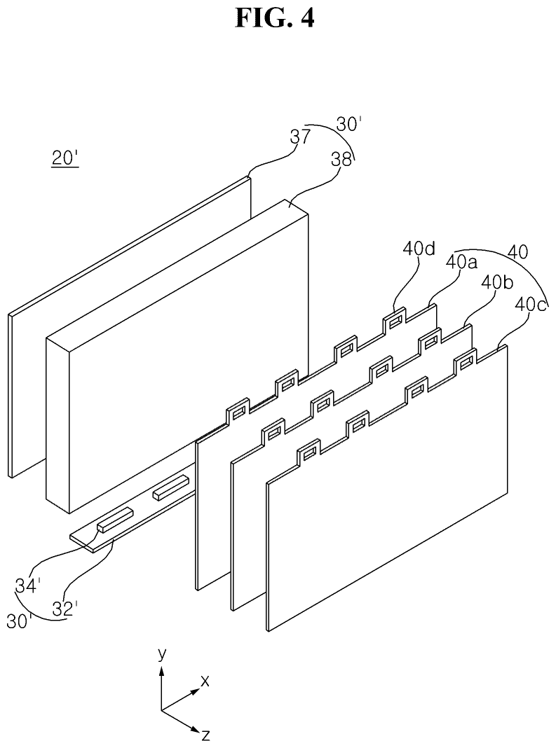

Referring to FIG. 4, a backlight unit 20′ may include an optical layer 30′ and the optical sheet 40. The optical layer 30′ may be disposed between the frame 60 and the display panel 10. The optical layer 30′ may be supported by the frame 60. The optical layer 30′ may include a substrate 32′, at least one light source 34′, a reflective sheet 37, and a light guide plate 38.

The light guide plate 38 may be disposed between the frame 60 and the optical sheet 40 and may be supported by the frame 60.

The substrate 32′ may be adjacent to a periphery of the light guide plate 38 and may be coupled to one side of the guide panel 13. For example, the substrate 32′ may be adjacent to a lower side of the light guide plate 38. The substrate 32′ may be made of at least one of polyethylene terephthalate (PET), glass, polycarbonate (PC), and silicon. The substrate 32′ may be a printed circuit board (PCB).

At least one light source 34′ may be mounted on the substrate 32′. A plurality of light sources 34′ may be spaced apart from each other on the substrate 32′. An electrode pattern for connecting an adapter and the light sources 34′ may be formed on the substrate 32′. For example, a carbon nano tube electrode pattern for connecting the light source 34′ and an adapter may be formed on the substrate 32′.

For example, the light source 34′ may be a light emitting diode (LED) chip or an LED package including at least one LED chip. The light source 34′ may be configured as a white LED or a colored LED emitting light of at least one of red, green, and blue colors, and the like. The colored LED may include at least one of a red LED, a green LED, and a blue LED. The light source 34′ may be referred to as an optical assembly 34′.

The reflective sheet 37 may be disposed between the frame 60 and the light guide plate 38 and may be supported by the frame 60. The reflective sheet 37 may include at least one of a metal and metal oxide which are reflective materials. For example, the reflective sheet 37 may include a metal and/or metal oxide having high reflectance, such as at least one of aluminum (Al), silver (Ag), gold (Au), and titanium dioxide (TiO2).

Accordingly, the light source 34′ may provide light to the edges of the light guide plate 38. Light entering the light guide plate 38 may be directed forward by the light guide plate 38 and the reflective sheet 37.

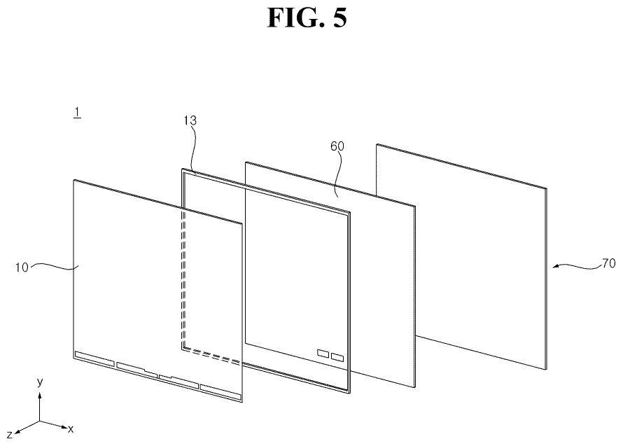

Referring to FIG. 5, the display device 1 may include the display panel 10, the guide panel 13, the frame 60, and the back cover 70.

The display panel 10 may form a front surface of the display device 1 and may display an image. The display panel 10 may divide an image into a plurality of pixels and may output the image while controlling color, brightness, and chroma of the respective pixels. The display panel 10 may be divided into an active area, in which an image is displayed, and a de-active area in which the image is not displayed. The display panel 10 may generate light corresponding to red, green, or blue color in response to a control signal. The display panel 10 may be referred to as an OLED panel.

The guide panel 13 may surround a periphery of the display panel 10 and may cover a side surface of the display panel 10. The guide panel 13 may be coupled to the display panel 10 or may support the display panel 10. The guide panel 13 may be referred to as a middle cabinet 13, a panel guide 13, or an inner frame 13.

The frame 60 may be disposed at the rear of the display panel 10, and the display panel 10 may be coupled to the frame 60. Edges of the frame 60 may be fixed to the guide panel 13. Electronic parts may be mounted to the frame 60. For example, the frame 60 may include a metal material such as an aluminum alloy and the like. The frame 60 may be referred to as a main frame 60, a module cover 60, or a bottom cover 60.

The back cover 70 may cover the rear of the frame 60. The back cover 70 may be coupled to the frame 60. For example, the back cover 70 may be an injection-molded product of a resin material. In another example, the back cover 70 may include a metal material.

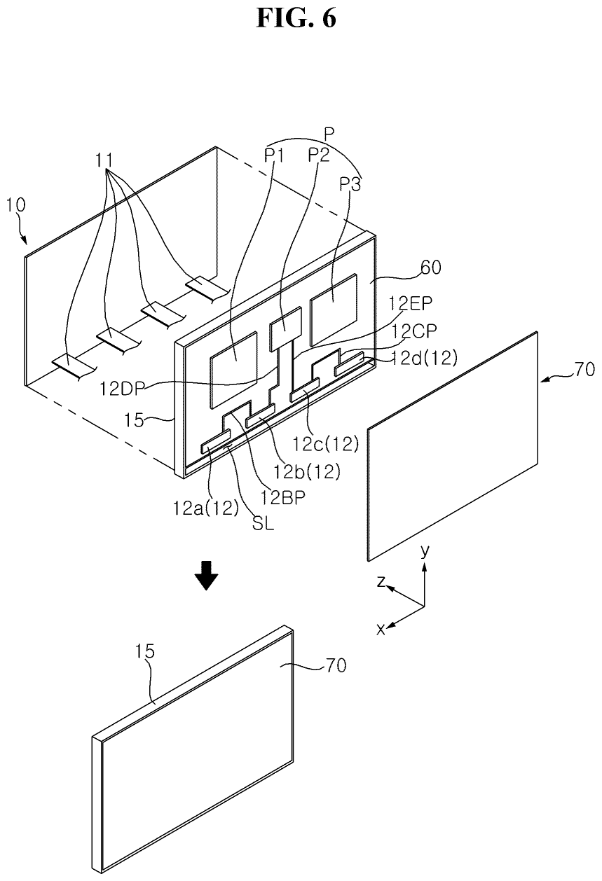

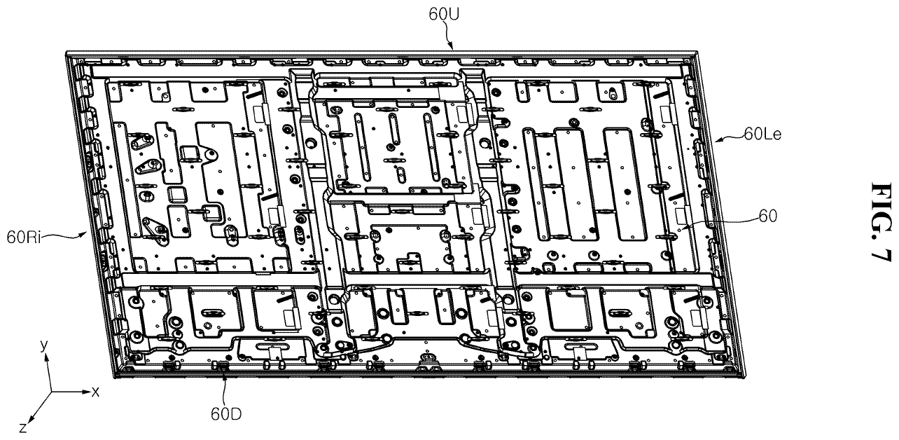

Referring to FIGS. 6 and 7, a board P may be mounted on a rear surface of the frame 60. A plurality of electronic elements may be mounted on the board P. The board P may be a printed circuit board (PCB) and may be electrically connected to electronic parts of the display device.

A plurality of boards P1, P2, and P3 may be mounted on the rear surface of the frame 60. A power supply board P1 may supply power to the respective components of the display device. A timing controller board P2 may provide an image signal to the display panel 10. A main board P3 may control the respective components of the display device. For example, the power supply board P1 may be adjacent to the left side 60Le of the frame 60, the main board P3 may be adjacent to the right side 60Ri of the frame 60, and the timing controller board P2 may be disposed between the power supply board P1 and the main board P3.

A first cable 11 may be adjacent to the lower side of the display panel 10 and may be electrically connected to the display panel 10. The first cable 11 may pass through a slit SL formed in a lower side 60D of the frame 60. Alternatively, the first cable 11 may pass through a cable hole (not shown) formed in the frame 60. For example, the first cable 11 may be a Chip On Film (COF).

A source Printed Circuit Board (PCB) 12 may be adjacent to the lower side 60D of the frame 60 and may be coupled to the rear surface of the frame 60. The source PCB 12 may be referred to as an S-PCB 12 or a substrate 12. The source PCB 12 may be electrically connected to the first cable 11. For example, a plurality of source PCBs 12a, 12b, 12c, and 12d may be spaced apart from each other along the lower side 60D of the frame 60 and may be electrically connected to the plurality of first cables 11.

Second cables 12BP, 12CP, 12DP, and 12EP may be disposed at the rear of the frame 60 and may be electrically connected to the source PCB 12 and the timing controller board P2. A first bridge cable 12BP may electrically connect a first source PCB 12a and a second source PCB 12b, and a second bridge cable 12CP may electrically connect a third source PCB 12c and a fourth source PCB 12d. A first connecting cable 12DP may electrically connect the second source PCB 12b and the timing controller board P2, and a second connecting cable 12EP may electrically connect the third source PCB 12c and the timing controller board P2. For example, the second cables 12BP, 12CP, 12DP, and 12EP may be Flexible Flat Cables (FFC). Meanwhile, the timing controller board P2 may be integrated into the main board P2, in which case the second cables 12BP, 12CP, 12DP, and 12EP may be electrically connected to the main board P3.

Accordingly, the timing controller board P2 or the main board P3 may provide digital video data and timing control signals to the display panel 10 through the source PCB 12.

The back cover 70 may be disposed at the rear of the frame 60 and may be coupled to the frame 60. The board P may be disposed between the frame 60 and the back cover 70 and may be covered by the back cover 70.

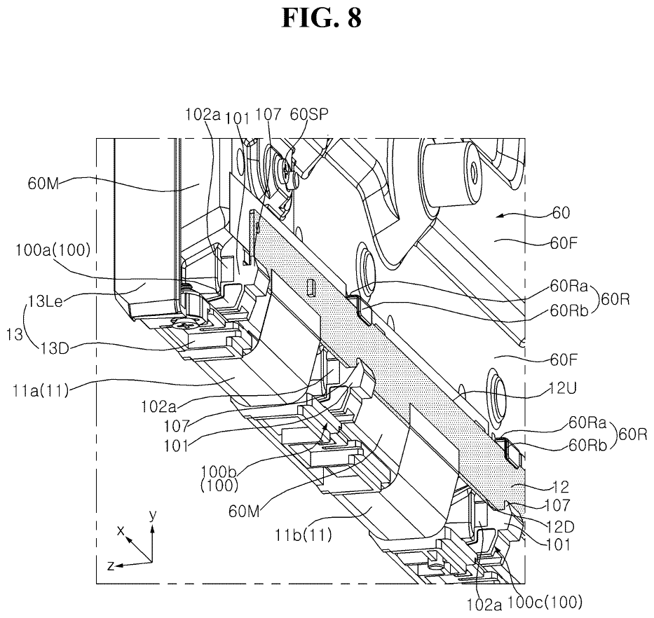

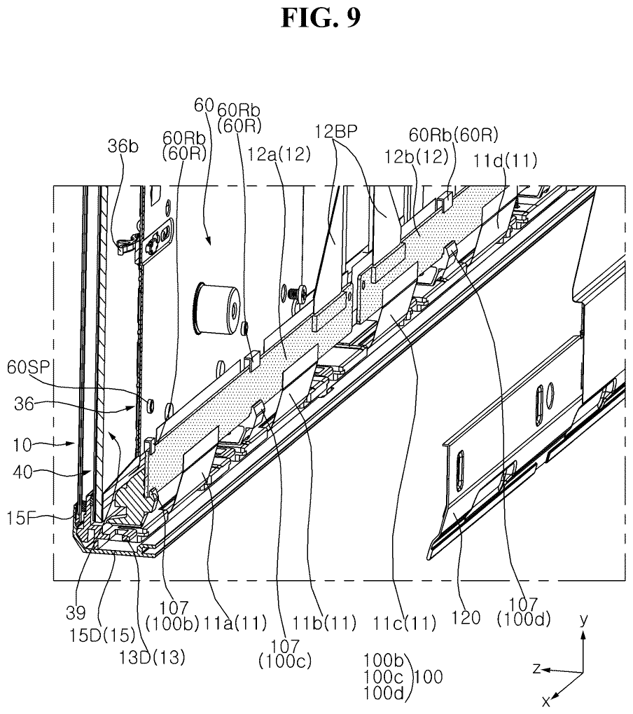

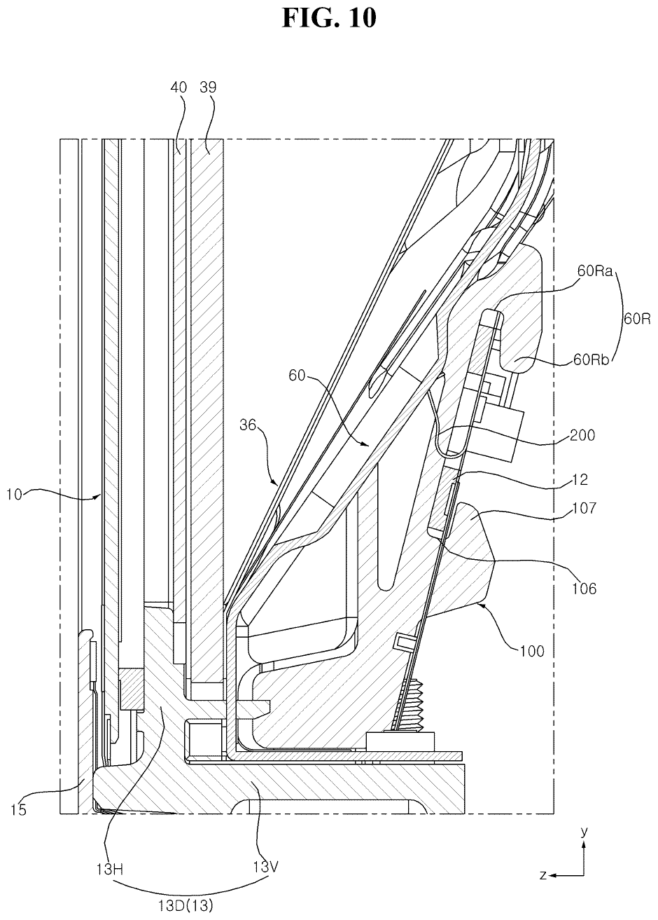

Referring to FIGS. 8 to 10, the guide panel 13 may extend along the edges of the frame 60. A left part 13Le of the guide panel 13 may extend along a left side of the frame 60. A right part of the guide panel 13 may extend along a right side of the frame 60. An upper part of the guide panel 13 may extend along an upper side of the frame 60. A lower part 13D of the guide panel 13 may extend along a lower side of the frame 60.

A plurality of first cables 11 may be disposed below the lower side 13D of the guide panel 13. The plurality of source PCBs 12, connected to the plurality of first cables 11, may be adjacent to the lower side of the frame 60 and may be disposed at the rear of the frame 60.

A plurality of first fixing parts 100 may be adjacent to a lower side 12D of the source PCB 12 and may protrude rearward from the frame 60. For example, a first fixing part 100 may be removably coupled to the frame 60. A first groove 106 may be formed in one surface of the first fixing part 100 facing the lower side 12D of the source PCB 12, and the lower side 12D of the source PCB 12 may be inserted into the first groove. A first protrusion 107 may define a portion of a boundary of the first groove 106, and a rear surface of the source PCB 12 may be caught by a front surface of the first protrusion 107.

A plurality of second fixing parts 60R may be adjacent to an upper side 12U of the source PCB 12 and may protrude rearward from the frame 60. The plurality of second fixing parts 60R may be vertically aligned or misaligned with the plurality of first fixing parts 100. For example, the second fixing part 60R may be a rib formed on the frame 60. A second groove 60Ra may be formed in one surface of the second fixing part 60R facing the upper side 12U of the source PCB 12, and the upper side 12U of the source PCB 12 may be inserted into the second groove. A second protrusion 60Rb may define a portion of a boundary of the second groove 60Ra, and the rear surface of the source PCB 12 may be caught by the front surface of the second protrusion 60Rb.

Accordingly, the source PCB 12 may be fixed between the first fixing part 100 and the second fixing part 60R. Likewise, different types of substrates may also be fixed between components such as the first and second fixing parts 100 and 60R, to be coupled to the frame 60. That is, the type of substrate, fixed between the components such as the first and second fixing parts 100 and 60R, is not limited to the source PCB.

A shield plate 120 may cover the rear of the source PCB 12 and may be removably coupled to the frame 60. Accordingly, the shield plate 120 may protect circuits and elements mounted on the rear surface of the source PCB 12. Meanwhile, the shield plate 120 may be omitted, in which case the back cover 70 may protect the circuits and elements mounted on the rear surface of the source PCB 12.

Meanwhile, the guide panel 13 may include a vertical part 13V and a horizontal part 13H. The vertical part 13V may cover the edges of the display panel 10 and the edges of the frame 60. The horizontal part 13H may protrude from the vertical part 13V and between the display panel 10 and the optical sheet 40. The display panel 10 may be coupled onto the horizontal part 13H by an adhesive pad.

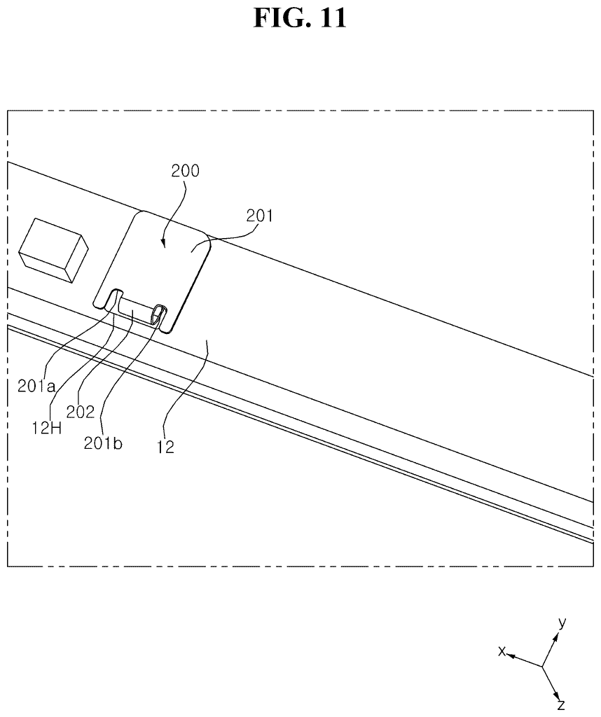

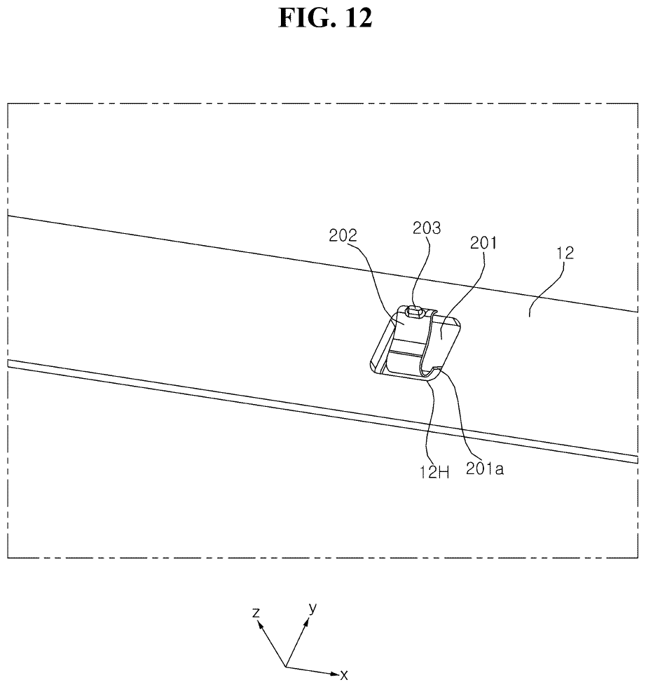

Referring to FIGS. 11 and 12, the source PCB 12 may be a single sided PCB. The elements and circuits may be mounted or formed on the rear surface of the source PCB 12. A holder 200 may include an electrically conductive material such as metal. The holder 200 may include a body 201 and a leg 202. The holder 200 may be referred to as a clip 200 or a connector 200.

The body 201 may have a generally flat plate shape. The body 201 may be seated on the rear surface of the source PCB 12 and may be electrically connected to the source PCB 12. The body 201 may be welded to the rear surface of the source PCB 12. The body 201 may be attached to the rear surface of the source PCB 12 using Surface Mounter Technology (SMT).

The leg 202 may protrude forward from the body 201 and may pass through a hole 12H of the source PCB 12. Here, the hole 12H may be formed by penetrating the source PCB 12 in the front-rear direction, and a portion of the hole 12H may be covered by the body 201.

A pair of slits 201a and 201b may be formed in the body 201 and may be opposite to each other with respect to the leg 202. The pair of slits 201a and 201b may be formed inward from one side of the body 201. The pair of slits 201a and 201b may face the hole 12H of the source PCB 12. A first slit 201a may be formed on the left side of the leg 202 and a second slit 201b may be formed on the right side of the leg 202.

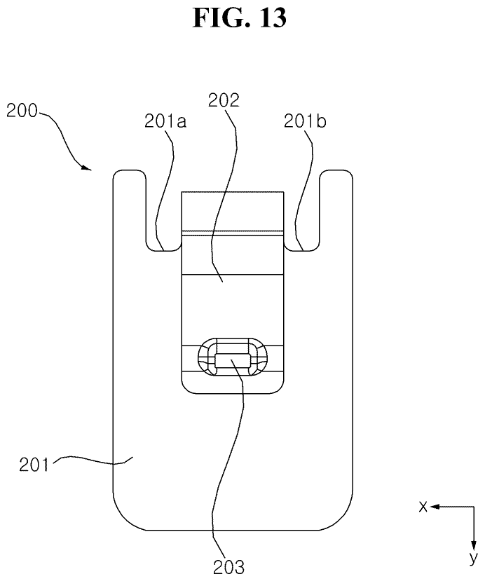

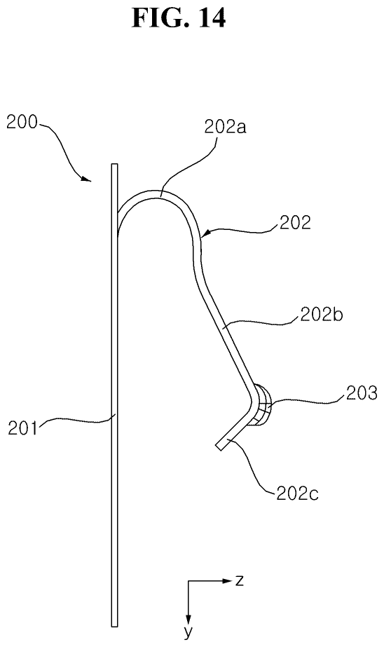

Referring to FIGS. 13 and 14, the leg 202 may be curled forward from the body 201. The leg 202 may have a generally C-shape and may have elasticity. The leg 202 may be referred to as a tension part 202 or an open ring 202 having one end fixed to the body 201.

The leg 202 may be bent at least once. The leg 202 may include first to third parts 202a, 202b, and 202c. The first part 202a may be curled forward from the body 201. The second part 202b may be bent from a distal end of the first part 202a and may extend obliquely from the body 201 in a direction away from the body 201. The third part 202c may be bent from a distal end of the second part 202b toward the body 201 and may be spaced apart from the body 201. In this case, a portion between the second part 202b and the third part 202c may form a front end of the leg 202.

Accordingly, the leg 202 may have tension to move forward and backward and may have a certain level of rigidity.

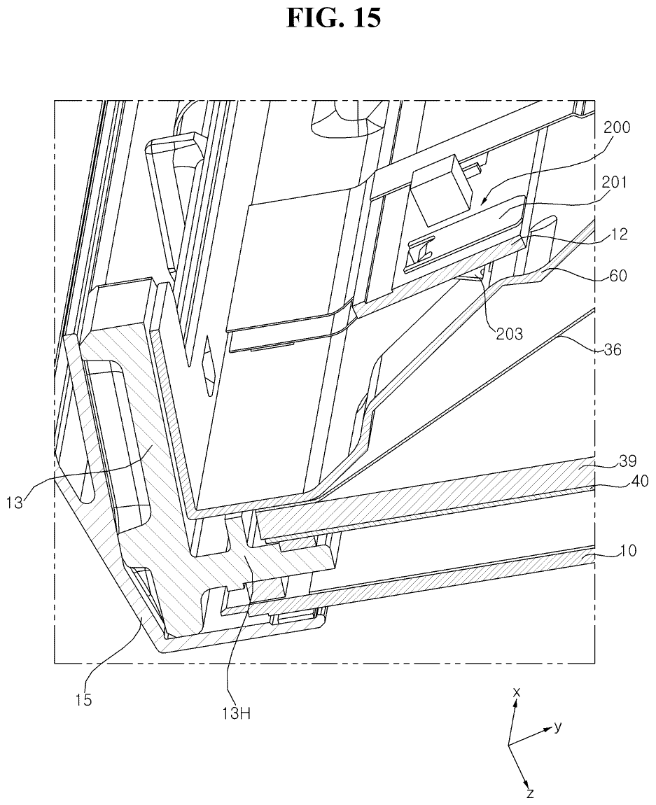

Referring to FIGS. 14 and 15, a contact part 203 may protrude from the front end of the leg 202, i.e., the portion between the second part 202b and the third part 202c of the leg 202, toward the frame 60, and may contact the frame 60. The leg 202 may be elastically deformed toward the body 201 while being in contact with the frame 60. In this case, by a restoring force of the leg 202, the contact between the contact part 203 and the frame 60 may be maintained continuously. For example, the contact part 203 may be formed by being pressed from a front surface of the leg 202 toward the rear. In this manner, the rigidity of the contact part 203 may be improved. Here, the frame 60 may include an electrically conductive material.

Accordingly, the source PCB 12 may be grounded to the frame 60 via the holder 200. That is, the holder 200 may reduce or prevent Electromagnetic Interference (EMI) noise in the source PCB 12. Further, the tension of the leg 202 may minimize sagging of the source PCB 12 toward the frame 60. That is, the holder 200 may support the source PCB 12 on the frame 60. Likewise, other types of substrates may be grounded to the frame 60 via the holder 200 and may be supported by the holder 200. That is, the type of substrate grounded to the frame 60 via the holder 200 is not limited to the PCB.

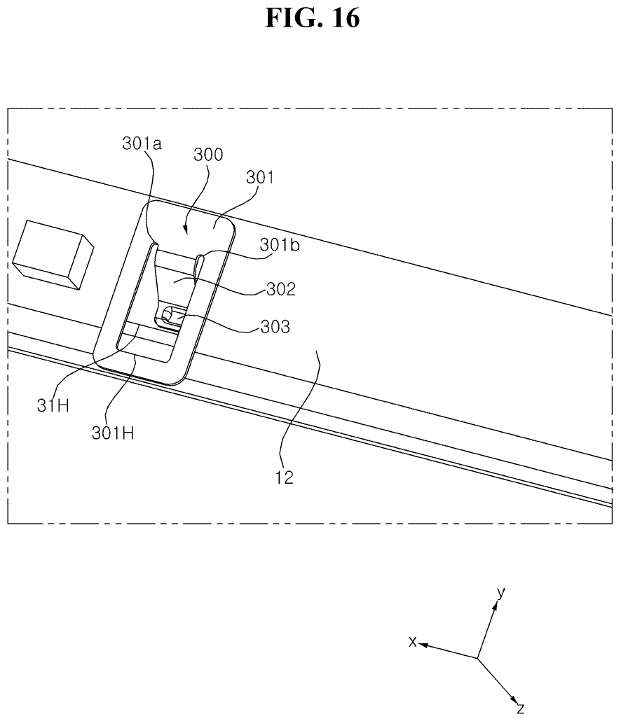

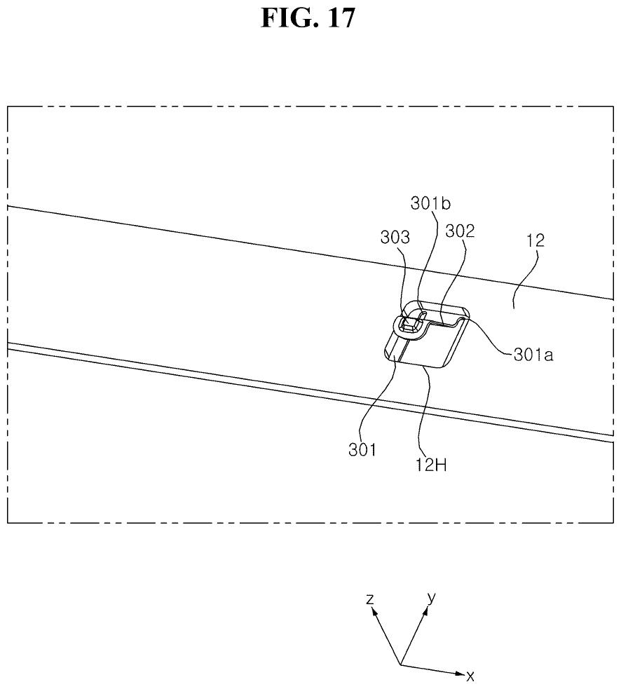

Referring to FIGS. 16 and 17, the source PCB 12 may be a single sided PCB. The elements and circuits may be mounted or formed on the rear surface of the source PCB 12. A holder 300 may include an electrically conductive material such as metal. The holder 300 may include a body 301 and a leg 302. The holder 300 may be referred to as a clip 300 or a connector 300.

The body 301 may have a generally flat plate shape. The body 301 may be seated on the rear surface of the source PCB 12 and may be electrically connected to the source PCB 12. The body 301 may be welded to the rear surface of the source PCB 12. The body 301 may be attached to the rear surface of the source PCB 12 using Surface Mounter Technology (SMT).

The leg 302 may protrude forward from the body 301 and may pass through the hole 12H of the source PCB 12. Here, the hole 12H may be formed by penetrating the source PCB 12 in the front-rear direction, and a portion of the hole 12H may be covered by the body 301.

A pair of slits 301a and 301b may be formed in the body 301 and may be opposite to each other with respect to the leg 302. The pair of slits 301a and 301b may be part of the hole 301H of the body 301, and the leg 302 may protrude from an inner surface of the hole 301H. The pair of slits 301a and 301b may face the hole 12H of the source PCB 12. A first slit 301a may be formed on the left side of the leg 302 and a second slit 301b may be formed on the right side of the leg 202.

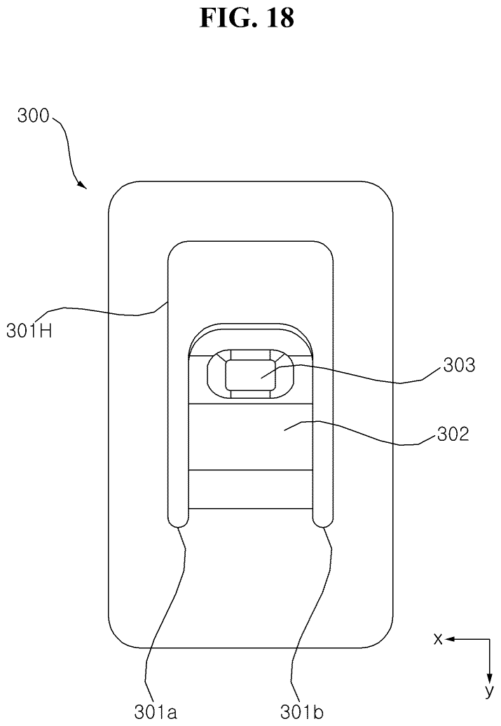

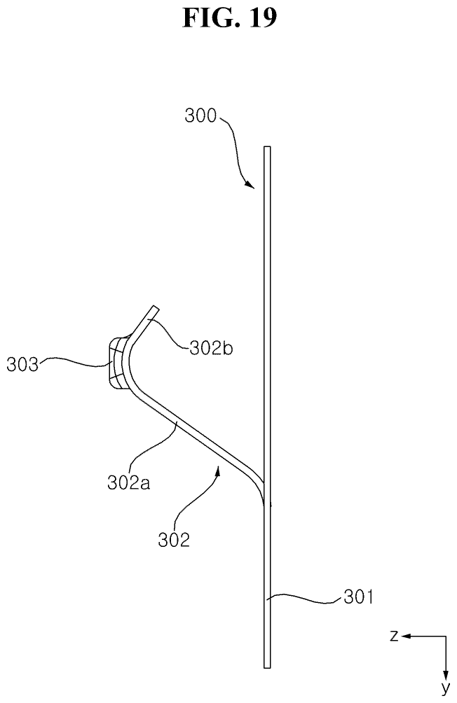

Referring to FIGS. 18 and 19, the leg 302 may be bent or curled forward from the body 301. The leg 302 may have a generally C-shape and may have elasticity. The leg 302 may be referred to as a tension part 302 or an open ring 302 having one end fixed to the body 301.

The leg 302 may be bent at least once. The leg 302 may include first and second parts 302a and 302b. The first part 302a may be bent forward from an inner surface of the hole 301H of the body 301 and may extend obliquely from the body 301 in a direction away from the body 301. The second part 302b may be bent from a distal end of the first part 302a toward the body 301 and may be spaced apart from the body 301. In this case, a portion between the first part 2023a and the second part 302b may form a front end of the leg 302.

Accordingly, the leg 302 may have tension to move forward and backward and may have a certain level of rigidity.

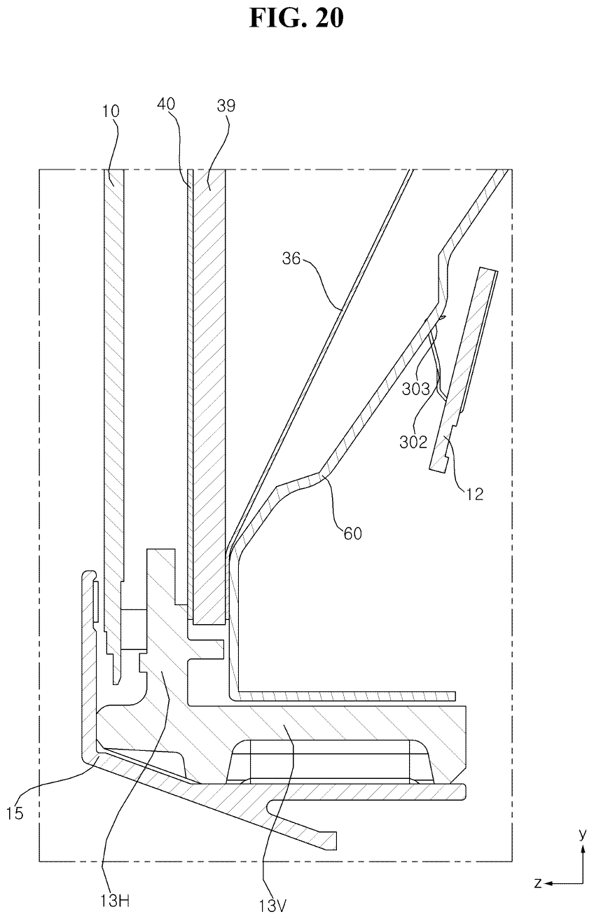

Referring to FIGS. 19 and 20, a contact part 303 may protrude from the front end of the leg 302, i.e., the portion between the first part 302a and the second part 302b of the leg 302, toward the frame 60, and may contact the frame 60. The leg 302 may be elastically deformed toward the body 201 while being in contact with the frame 60. In this case, by a restoring force of the leg 302, the contact between the contact part 303 and the frame 60 may be maintained continuously. For example, the contact part 303 may be formed by being pressed from a front surface of the leg 302 toward the rear. In this manner, the rigidity of the contact part 303 may be improved. Here, the frame 60 may include an electrically conductive material.

Accordingly, the source PCB 12 may be grounded to the frame 60 via the holder 300. That is, the holder 300 may reduce or prevent Electromagnetic Interference (EMI) noise in the source PCB 12. Further, the tension of the leg 302 may minimize sagging of the source PCB 12 toward the frame 60. That is, the holder 200 may support the source PCB 12 on the frame 60. Likewise, other types of substrates may be grounded to the frame 60 via the holder 200 and may be supported by the holder 300. That is, the type of substrate grounded to the frame 60 via the holder 300 is not limited to the PCB.

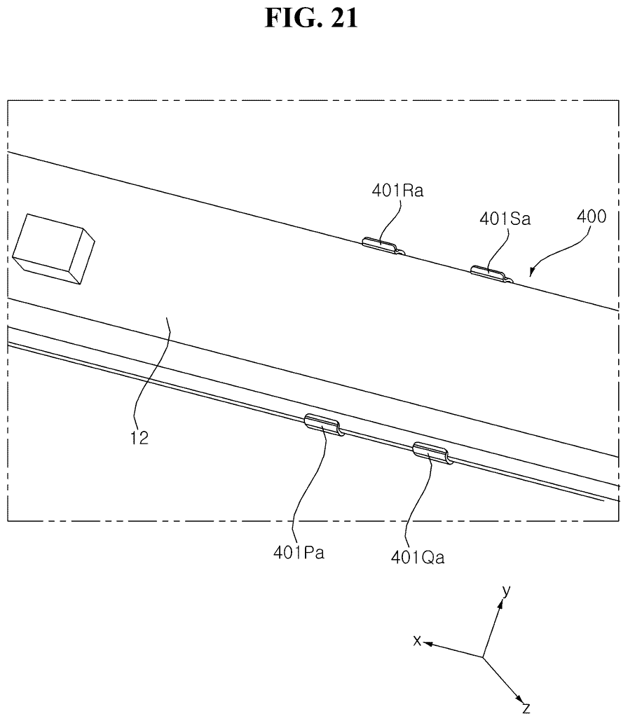

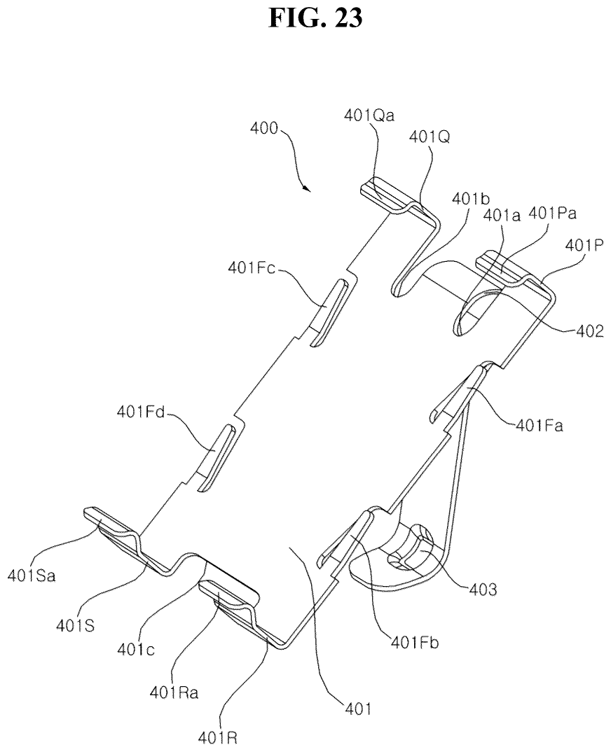

Referring to FIGS. 21 and 23, the source PCB 12 may be a single sided PCB. The elements and circuits may be mounted or formed on the rear surface of the source PCB 12. A holder 400 may include an electrically conductive material such as metal. The holder 400 may include a body 401 and a leg 402. The holder 400 may be referred to as a clip 400 or a connector 400.

The body 401 may have a generally flat plate shape. The body 401 may form the front surface of the source PCB 12. Bent portions 401Fa, 401Fb, 401Fc, and 401Fd may be cut from the body 401 to be bent toward the front surface of the source PCB 12, and may contact the front surface (e.g., an exposed copper foil portion) of the source PCB 12 to be electrically connected to the source PCB 12. A first bent portion 401Fa and a second bent portion 401Fb may be formed on the left side of the body 401 and may be spaced apart from each other along the left side. A third bent portion 401Fc and a fourth bent portion 401Fd may be formed on the right side of the body 401 and may be spaced apart from each other along the right side. The bent portions 401Fa, 401Fb, 401Fc, and 401Fd may be elastically deformed while being in contact with the front surface of the source PCB 12. In this case, the contact between the bent portions 401Fa, 401Fb, 401Fc, and 401Fd and the source PCB 12 may be maintained continuously.

A plurality of fixing parts 401P, 401Q, 401R, and 401S may be formed on the lower side and upper side of the body 401. A first fixing part 401P may protrude rearward from the lower side of the body 401 and may be caught by a lower end of the source PCB 12.

A first hook 401Pa, bent from a distal end of the first fixing part 401P, may be latched to a rear surface of the source PCB 12. A second fixing part 401Q, which is spaced apart from the first fixing part 401P, may protrude rearward from the lower side of the body 401, and may be caught by the lower end of the source PCB 12. A second hook 401Qa, bent from a distal end of the second fixing part 401Q, may be latched to the rear surface of the source PCB 12. The first and second fixing parts 401P and 401Q may be referred to as lower fixing parts 401P and 401Q.

A third fixing part 401R may protrude rearward from the upper side of the body 401 and may be caught by an upper end of the source PCB 12. A third hook 401Ra, bent from a distal end of the third fixing part 401R, may be caught by the rear surface of the source PCB 12. A fourth fixing part 401S, which is spaced apart from the third fixing part 401R, may protrude rearward from the lower side of the body 401 and may be caught by the upper end of the source PCB 12. A fourth hook 401Sa, bent from a distal end of the fourth fixing part 401S, may be latched to the rear surface of the source PCB 12. Accordingly, the holder 400 may be coupled to the source PCB 12. The third and fourth fixing parts 401R and 401S may be referred to as upper fixing parts 401R and 401S.

The leg 402 may protrude forward from the body 401. The leg 402 may be disposed between the first and second bent portions 401Fa and 401Fb and the third and fourth bent portions 401Fc and 401Fd.

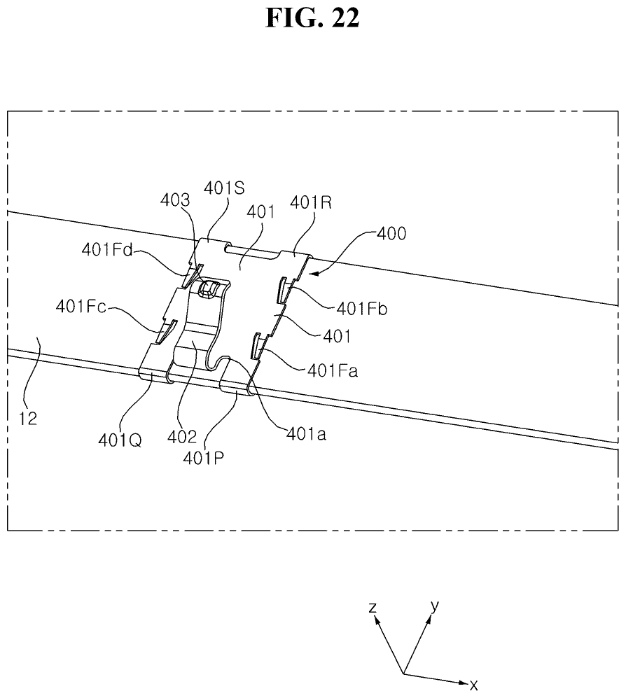

A pair of slits 401a and 401b may be formed in the body 410 and may be opposite to each other with respect to the leg 402. The pair of slits 401a and 401b may be formed inward from one side of the body 401. The pair of slits 401a and 401b may face the front surface of the source PCB 12 (see FIG. 22). A first slit 401a may be formed on the left side of the leg 402 and a second slit 201b may be formed on the right side of the leg 402.

The leg 402 may be curled forward from the body 401. The leg 402 may have a generally C-shape and may have elasticity. The leg 402 may be referred to as a tension part 402 or an open ring 402 having one end fixed to the body 401.

The leg 402 may be bent at least once. The leg 402 may include first to fourth parts 402a, 402b, 402c, and 402d. The first part 402a may be curled from the body 401. The second part 402b may be bent from a distal end of the first part 402a and may extend in a direction parallel to the body 401. The third part 402c may be bent from a distal end of the second part 402b and may extend obliquely from the body 401 in a direction away from the body 401. The fourth part 402d may be bent from a distal end of the third part 402c toward the body 401 and may be spaced apart from the body 401. In this case, a portion between the third part 402c and the fourth part 402d may form a front end of the leg 402.

Accordingly, the leg 402 may have tension to move forward and backward and may have a certain level of rigidity.

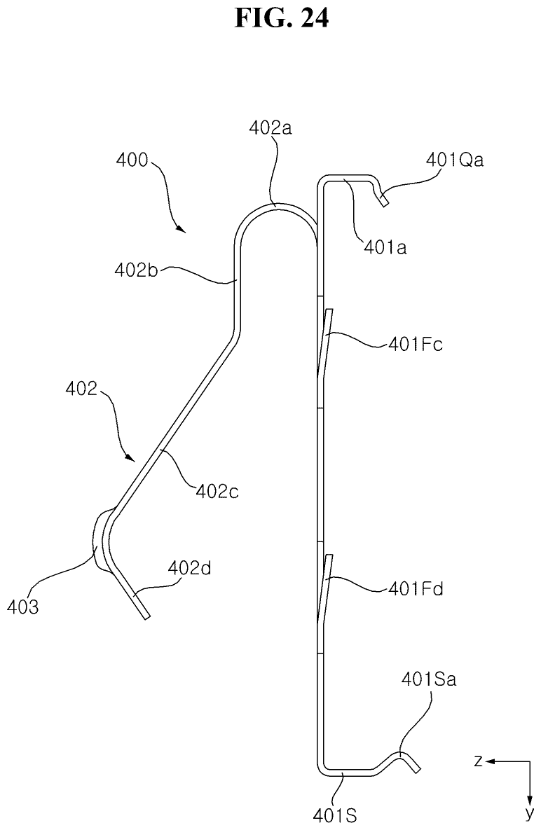

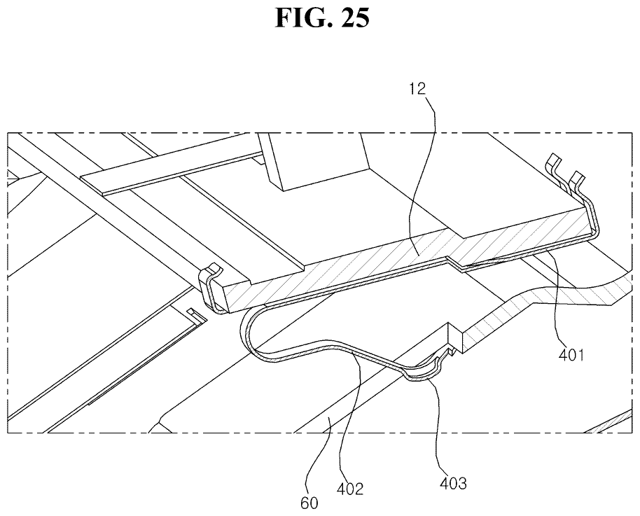

Referring to FIGS. 24 and 25, a contact part 403 may protrude from the front end of the leg 402, i.e., the portion between the third part 402c and the fourth part 402d of the leg 402, toward the frame 60, and may contact the frame 60. The leg 402 may be elastically deformed toward the body 401 while being in contact with the frame 60. In this case, by the tension of the leg 402, the contact between the contact part 403 and the frame 60 may be maintained continuously. For example, the contact part 403 may be formed by being pressed from a front surface of the leg 402 toward the rear. In this manner, the rigidity of the contact part 403 may be improved. Here, the frame 60 may include an electrically conductive material.

Accordingly, the source PCB 12 may be grounded to the frame 60 via the holder 400. That is, the holder 400 may reduce or prevent Electromagnetic Interference (EMI) noise in the source PCB 12. Further, the tension of the leg 402 may minimize sagging of the source PCB 12 toward the frame 60. That is, the holder 400 may support the source PCB 12 on the frame 60. Likewise, other types of substrates may be grounded to the frame 60 via the holder 400 and may be supported by the holder 400. That is, the type of substrate grounded to the frame 60 via the holder 400 is not limited to the PCB.

Referring to FIGS. 1 to 25, a display device according to an aspect of the present disclosure may include: a display panel; a frame which is disposed at a rear of the display panel, and to which the display panel is coupled; a substrate coupled to the frame at a rear of the frame; and a holder disposed between the frame and the substrate and coupled to the substrate, wherein: the frame and the holder may be electrically conductive; and the holder may include a body contacting the substrate, and a leg protruding from the body toward the frame and elastically deformed while being in contact with the frame.

The display device may further include a timing controller board, wherein the substrate may be a source PCB electrically connected to the display panel and the timing controller board.

The leg may have a first end fixed to the body and a second end spaced apart from the body, and may be bent at least once.

The leg may include: a first part curled from the body toward the frame; a second part bent from a distal end of the first part, and extending in a direction away from the body; and a third part bent from a distal end of the second part toward the body, and spaced apart from the body.

The holder may further include a contact part formed by being pressed from one surface of the leg toward the frame, and making contact with the frame.

The substrate may be a single sided PCB having a rear surface on which a circuit is formed, wherein: the body may be seated on the rear surface of the substrate; and the leg may protrude from the body toward the frame and may pass through a hole of the substrate.

The holder may further include a pair of slits formed in the body and opposite to each other with respect to the leg, wherein the pair of slits may face the hole of the substrate.

The body may be welded to the rear surface of the substrate.

The substrate may be a single sided PCB having a rear surface on which a circuit is formed, wherein the body may face a front surface of the substrate, wherein the holder may further include a bent portion which is cut from the body to be bent toward the front surface of the substrate, and which contacts the front surface of the substrate.

The bent portion may be elastically deformed while being in contact with the front surface of the substrate.

The holder may include: a lower fixing part having a hook which protrudes rearward from one side of the body, and which is latched to the rear surface of the substrate; and an upper fixing part having a hook which protrudes rearward from another side of the body, and which is latched to the rear surface of the substrate.

The holder may include a pair of slits formed in the body and opposite to each other with respect to the leg, wherein the pair of slits may face the front surface of the substrate.

The display device according to the present disclosure has the following effects.

According to at least one of the embodiments of the present disclosure, a structure for allowing a substrate to make ground contact with a frame may be provided.

According to at least one of the embodiments of the present disclosure, a structure for reducing Electromagnetic Interference (EMI) noise in a substrate may be provided.

According to at least one of the embodiments of the present disclosure, a structure for minimizing sagging of a substrate toward a frame may be provided.

According to at least one of the embodiments of the present disclosure, various examples of a holder that supports a substrate on a frame may be provided.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

What is claimed is:

1. A display device comprising:
a display panel;
a frame which is disposed at a rear of the display panel, and to which the display panel is coupled;
a substrate coupled to a rear of the frame; and
a holder coupled to the substrate and disposed between the frame and the substrate,
wherein:
the frame and the holder are electrically conductive; and
the holder comprises a body contacting the substrate, and a leg having elasticity and protruding from the body toward the frame to be in contact with the frame.

2. The display device of claim 1, further comprising a timing controller board,
wherein the substrate is a source PCB electrically connected to the display panel and the timing controller board.

3. The display device of claim 1, wherein the leg has a first end fixed to the body and a second end spaced apart from the body, and is bent at least once between the first end and the second end.

4. The display device of claim 3, wherein the leg further comprises:
a first part curved away from the body toward the frame;
a second part bent away from the body from an end of the first part; and
a third part bent toward the body from an end of the second part,
wherein an end of the third part is spaced apart from the body.

5. The display device of claim 1, wherein the holder further comprises a contact part at a front surface of the leg and configured to contact the frame.

6. The display device of claim 1, wherein the substrate is a single sided PCB having a rear surface on which a circuit is formed,
wherein:
the body is seated on the rear surface of the substrate; and
the leg protrudes from the body toward the frame and passes through a hole of the substrate.

7. The display device of claim 6, wherein the holder further comprises a pair of slits formed at the body and disposed opposite each other with respect to the leg,
wherein the pair of slits are open toward the hole of the substrate.

8. The display device of claim 6, wherein the body is welded to the rear surface of the substrate.

9. The display device of claim 1, wherein the substrate is a single sided PCB having a rear surface on which a circuit is formed,
wherein the body is disposed at a front surface of the substrate and comprises a bent portion which is cut from the body to be bent toward and contact the front surface of the substrate.

10. The display device of claim 9, wherein the bent portion is elastically deformed to maintain contact with the front surface of the substrate.

11. The display device of claim 9, wherein the holder comprises:
a lower fixing part having a hook which protrudes rearward from one side of the body, and which is latched to the rear surface of the substrate; and
an upper fixing part having a hook which protrudes rearward from another side of the body, and which is latched to the rear surface of the substrate.

12. The display device of claim 9, wherein the holder comprises a pair of slits formed at the body and disposed opposite each other with respect to the leg,
wherein the pair of slits are open toward a side of the body.
